(19) United States
(12) Patent Application Publication
(10) Pub. No.: US 2007/0178032 A1
(43) Pub. Date: Aug. 2, 2007

(54) Transparent ferromagnetic compound containing no magnetic impurity such as transition metal or rare earth metal and forming solid solution with element having imperfect shell, and method for adjusting ferromagnetic characteristics thereof

(75) Inventors: Hiroshi Yoshida, Hyogo (JP); Kazuhide Kenmochi, Shizuoka (JP); Masayoshi Seike, Hyogo (JP); Kazunori Sato, Osaka (JP); Akira Yanase, Nara (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: JAPAN SCIENCE AND TECHNOLOGY AGENCY, KAWAGUCHI-SHI (JP)

(21) Appl. No.: 10/590,289

(22) PCT Filed: Feb. 25, 2005
(86) PCT No.: PCT/JP05/03196

§ 371 Date: Aug. 23, 2006

(30) Foreign Application Priority Data
Feb. 27, 2004 (JP) 2004-055017

(51) Int. Cl. C01F 1/00; B05D 5/12; H01F 1/00; C01D 3/08; C30B 15/00; C22B 26/20

(52) U.S. Cl. 423/155; 427/127; 252/62.51 R; 117/954; 117/15; 423/179

(57) ABSTRACT

A single-crystal transparent ferromagnetic compound that transmits light and has significant ferromagnetic properties is selected from the group consisting of alkaline earth chalcogenides, alkali chalcogenides, I-VII compounds, II-VI compounds, III-V compounds, IV-VI₂ compounds, IV-IV compounds, and II-VII₂ compounds. At least one element having an incomplete outermost p-electron shell, such as B, C, N, O, F, Si, or Ge, is dissolved in the compound so that the compound has a ferromagnetic transition temperature of room temperature or higher. The ferromagnetic properties of the compound are controlled by adjustment of the concentration of the element having an incomplete outermost p-electron shell and valence electron control through, for example, the addition of an acceptor and a donor.

### TECHNICAL FIELD

The present invention relates to single-crystal, transparent wide-band-gap compounds having ferromagnetic properties and methods for controlling the ferromagnetic properties thereof. Specifically, the invention relates to a transparent, ferromagnetic wide-band-gap compound having a large magneto-optical effect and desired ferromagnetic properties, for example, a desired ferromagnetic transition temperature, and a method for controlling the ferromagnetic properties thereof.

### BACKGROUND ART

Known transparent ferromagnetic materials containing magnetic impurities, such as 3d transition metals, 4d transition metals, 5d transition metals, and lanthanide-series rare earth metal elements, absorb light in a specific visible region by exciting d electrons or f electrons within the shells thereof (Patent Documents 1 to 7 and Non-Patent Documents 1 to 5).

Alkaline earth chalcogenides are transparent, colorless compounds that have a band gap (Eg) of 3 eV or higher, transmit light in the visible to ultraviolet region and even in the extreme ultraviolet region, and produce excitons having a large binding energy. Realization of ferromagnetic materials with large spin-orbit interaction using alkaline earth chalcogenides has been expected to greatly advance the development of photonic devices such as spin transistors and optical isolators, which are based on spin degrees of freedom, and optical computers, which are based on coherent spin states, and devices for quantum information processing.

However, a completely spin-polarized transparent ferromagnetic state of a wide-band-gap compound, such as an alkaline earth chalcogenide, doped with an element having an incomplete outermost p shell has not yet been known. No report has been made on the realization of a ferromagnetic state of a wide-band-gap compound, such as an alkaline earth chalcogenide, with a high ferromagnetic transition temperature (Curie point).
Patent Document 1: Japanese Unexamined Patent Application Publication No. 2001-72496
Patent Document 2: Japanese Unexamined Patent Application Publication No. 2001-130915
Patent Document 3: Japanese Unexamined Patent Application Publication No. 2002-255695
Patent Document 4: Japanese Unexamined Patent Application Publication No. 2002-255698
Patent Document 5: Japanese Unexamined Patent Application Publication No. 2002-260922
Patent Document 6: Japanese Unexamined Patent Application Publication No. 2003-318026
Patent Document 7: Japanese Unexamined Patent Application Publication No. 2003-137698
Non-Patent Document 1: “Material Design of GaN-based Ferromagnetic Diluted Magnetic Semiconductors,” Kazunori Sato and Hiroshi Katayama-Yoshida, Jpn. J. Appl. Phys., Vol. 40, pp. L485-L487 (2001)
Non-Patent Document 2: “Stabilization of Ferromagnetic States by Electron Doping in Fe-, Co-, or Ni-doped ZnO,” Kazunori Sato and Hiroshi Katayama-Yoshida, Jpn. J. Appl. Phys., Vol. 40, pp. L334-L336 (2001)
Non-Patent Document 3: “Study of II-VI and III-V Ferromagnetic Semiconductors Doped with 4d Transition Metals,” Masayoshi Seike, Hiroshi Yoshida, Extended Abstracts of The 50th Spring Meeting of The Japan Society of Applied Physics and Related Societies, No. 1, p. 525, Mar. 27, 2003
Non-Patent Document 4: “Material Design of Half-Metallic Transparent Ferromagnetic Semiconductors Doped with 4d Transition Metals,” Masayoshi Seike, Akira Yanase, Hiroshi Yoshida, Extended Abstracts of The 64th Autumn Meeting of The Japan Society of Applied Physics, No. 1, p. 415, Aug. 30, 2003
Non-Patent Document 5: “Design of Method for Increasing Ferromagnetic Transition Temperature by δ Doping and Co-doping,” Yuki Oishi, VANAND, Hiroshi Yoshida, Extended Abstracts of The 64th Autumn Meeting of The Japan Society of Applied Physics, No. 1, p. 416, Aug. 30, 2003

### DISCLOSURE OF INVENTION

### Problems to be Solved by the Invention

Realization of a single-crystal thin film of a ferromagnetic compound that transmits light and has significant ferromagnetic properties is expected to facilitate realization of optical isolators, which are required for communicating large volumes of information, and high-density magneto-optical recording based on the magneto-optical effect of the compound. The realization of such a compound is also expected to lead to the production of electronic magneto-optical materials for application to devices required for ultra-high-speed, super-energy-saving communication of large volumes of information in the future based on spin degrees of freedom of electrons and light in addition to charge degrees of freedom. Furthermore, completely spin-polarized transparent ferromagnetic materials with a large magneto-optical effect have been demanded.

A compound such as an alkaline earth chalcogenide which transmits visible light and has stable transparent ferromagnetic properties with a magneto-optical effect, as described above, could be used in combination with a light-emitting device, such as a semiconductor laser, to produce circularly polarized light that varies with the magnetic state of the compound. Such a compound is expected to be applied to magneto-optical spin devices based on the large magneto-optical effect due to the large spin-orbit interaction of the compound in the fields of optical information communication and spintronics. For development of ferromagnetic memory, in which magnetization states are read according to their properties to circularly polarized light, a compound with desired ferromagnetic properties must be prepared by, for example, controlling the ferromagnetic transition temperature (Curie point) to such a temperature that the magnetization states are changed by irradiation with light (temperature slightly higher than room temperature).

### Means for Solving the Problems

The present invention provides a completely spin-polarized transparent ferromagnetic compound based on a transparent wide-band-gap compound. The present invention further provides a method for controlling the ferromagnetic properties of the transparent ferromagnetic compound, including the ferromagnetic transition temperature, in the production thereof.

The term “wide-band-gap compound” herein refers to compounds having a wide band gap, such as alkaline earth chalcogenides (e.g., CaO, MgO, SrO, and BaO), alkali chalcogenides (e.g., K₂S and Li₂O), I-VII compounds (e.g., NaCl and KCl), II-VI compounds (e.g., ZnO and ZnS), III-V compounds (e.g., GaN and GaAs), IV-VI₂ compounds (e.g., SiO₂ and GeO₂), IV-IV compounds (e.g., SiGe and GeC), and II-VII2 compounds (e.g., CaF₂ and CaCl₂). Alkaline earth chalcogenides (e.g., CaO, CaS, CaSe, and CaTe) are taken as examples in the description below, although the techniques described below can be applied to any of the wide-band-gap compounds described above.

The present inventors have conducted intensive studies on the formation of a single crystal having ferromagnetic properties using an alkaline earth chalcogenide, which is particularly suitable as a transparent material with its wide band gap and also has large lattice parameters. The studies have found that a single crystal (mixed crystal) can be successfully formed even if up to about 25 atomic percent of the chalcogen atoms are replaced with an element having an incomplete outermost p shell (e.g., B, C, N, O, F, Si, or Ge) by nonequilibrium crystal growth at low temperature.

According to the studies, the element having an incomplete outermost p-electron shell, such as C or N, imparts ferromagnetism to the alkaline earth chalcogenide when dissolved therein although the element normally exhibits no ferromagnetism. The element dopes the chalcogenide with holes or electrons (increases or decreases the number of electrons) by changing electron states.

That is, the element having an incomplete outermost p-electron shell provides an effect equivalent to that provided by adding holes or electrons to p electrons when dissolved in the alkaline earth chalcogenide. A stable, completely spin-polarized transparent ferromagnetic state can thus be achieved simply by dissolving the element having an incomplete outermost p-electron shell alone in the alkaline earth chalcogenide.

Further intensive studies by the present inventors have found that the element having an incomplete outermost p-electron shell, such as B, C, N, O, F, Si, or Ge, enters a high-spin state to allow, for example, the variation of ferromagnetic transition temperature, the stabilization of a ferromagnetic state relative to antiferromagnetic, spin-glass, and paramagnetic states, and the adjustment of the energy of the ferromagnetic state (to, for example, such an energy that the ferromagnetic state is normally maintained but can be changed to the spin-glass or paramagnetic state with only a slight change in the amount of energy). Such effects can be attained by, for example, changing the concentration of the dissolved element, dissolving a combination of two or more such elements, changing the concentration ratio thereof, and adding an n-type dopant and/or a p-type dopant. In addition, a mixed crystal formed by selectively dissolving two or more elements having an incomplete outermost p-electron shell can have a desired filtering function because the minimum transmission wavelength depends on the types of elements dissolved.

According to the studies, the concentration or mixing ratio of one or more elements having an incomplete outermost p-electron shell can be adjusted to achieve a single-crystal, completely spin-polarized transparent ferromagnetic (also referred to as “half-metallic ferromagnetic,” with one spin state having a band gap and the other being itinerant) alkaline earth chalcogenide having desired magnetic properties.

A completely spin-polarized transparent ferromagnetic alkaline earth chalcogenide according to the present invention contains at least one element having an incomplete outermost p-electron shell. The term “alkaline earth chalcogenide” herein refers to compounds including atoms of an alkaline earth metal (Be, Mg, Ca, Sr, Ba, or Ra) and a chalcogen (O, S, Se, or Te), such as BeO, BeS, BeSe, BeTe, MgO, MgS, MgSe, MgTe, CaO, CaS, CaSe, CaTe, SrO, SrS, SrSe, SrTe, BaO, BaS, BaSe, BaTe, RaO, RaS, RaSe, and RaTe.

The element having an incomplete outermost p shell can replace atoms of the chalcogen, such as O, S, Se, or Te, because the compound described above has large lattice parameters and thus exhibits weak hybridization between the orbitals of the host atoms and the impurity atoms. This compound can maintain its single-crystal structure, transparency, and completely spin-polarized ferromagnetism even if up to about 25 atomic percent of the chalcogen atoms are replaced with the element having an incomplete outermost p-electron shell by nonequilibrium crystal growth at low temperature, for example, about 250° C.

If the compound contains at least two elements having an incomplete outermost p-electron shell, impurity p-electron states originating therefrom hybridize with atomic orbitals of the host compound to form a narrow impurity band which produces a large electron correlation effect. This effect provides ferromagnetism, particularly, a completely spin-polarized transparent ferromagnetic state. The addition of such elements changes the ferromagnetic properties of the compound more directly than doping with holes or electrons, thus allowing the control of the ferromagnetic properties, including the ferromagnetic transition temperature. From a practical viewpoint, ferromagnetic transition temperatures of 300 K or higher are preferred for operation at room temperature or higher in application to spintronics.

If the compound is doped with at least one of an n-type dopant and a p-type dopant, injected carriers enter the narrow impurity band, which is formed in a band gap. The doping can change the number of electrons occupying the impurity p-electron states of the element having an incomplete outermost p-electron shell. The ferromagnetic properties of the compound can thus be controlled by valence electron control of the p electrons constituting the impurity band.

According to the present invention, the ferromagnetic properties of an alkaline earth chalcogenide are controlled by the following methods:
(1) Dissolution of at least one element having an incomplete outermost p shell in the alkaline earth chalcogenide and adjustment of the concentration thereof
(2) Addition of at least one of an n-type dopant and a p-type dopant and adjustment of the concentration thereof

Specifically, the ferromagnetic transition temperature can be controlled to a desired temperature by adjusting the concentrations described above (the concentrations of the element having an incomplete outermost p-electron shell and the dopant). In addition, the ferromagnetic state of the compound can be stabilized by dissolving the element having an incomplete outermost p-electron shell and the dopant to adjust the stabilization energy of the ferromagnetic state and to decrease the total energy with the kinetic energy of holes or electrons introduced by the element having an incomplete outermost p-electron shell and the dopant. The ferromagnetic state can also be stabilized by dissolving the element having an incomplete outermost p-electron shell and the dopant to control the magnitude and sign of interelemental magnetic interaction with the holes or electrons introduced by the element having an incomplete outermost p-electron shell.

Furthermore, a completely spin-polarized transparent ferromagnetic alkaline earth chalcogenide having desired optical filtering properties can be achieved by dissolving the element having an incomplete outermost p-electron shell and the dopant to control the magnitude and sign of interatomic magnetic interaction with the holes or electrons introduced by the element having an incomplete outermost p-electron shell and to control optical transmission properties through the dissolution of the element having an incomplete outermost p-electron shell.

### Advantages

The present invention thus provides a single-crystal, completely spin-polarized transparent ferromagnetic material produced only by dissolving an element having an incomplete outermost p-electron shell, such as B, C, N, O, F, Si, or Ge, in a compound such as an alkaline earth chalcogenide.

### BEST MODE FOR CARRYING OUT THE INVENTION

Next, a completely spin-polarized transparent ferromagnetic compound, a method for producing the compound, and a method for controlling the ferromagnetic properties thereof according to the present invention will be described below with reference to the drawings using an alkaline earth chalcogenide as an example. The techniques described above on alkaline earth chalcogenides, which have a wide band gap and large lattice parameters, can also be applied to any other compound having a wide band gap and large lattice parameters, such as alkali chalcogenides, I-VII compounds, II-VI compounds, III-V compounds, IV-VI₂ compounds, IV-IV compounds, and II-VII₂ compounds.

At least one element having an incomplete outermost p-electron shell is dissolved in the completely spin-polarized transparent ferromagnetic alkaline earth chalcogenide according to the present invention. A thin film of the alkaline earth chalcogenide containing the element having an incomplete outermost p-electron shell can be formed by, for example, MBE. FIG. 1 is a schematic diagram of an apparatus used for MBE. In FIG. 1, a chamber 1 capable of maintaining an ultrahigh vacuum of about 1.33×10⁻⁵ Pa includes a substrate holder 4 holding a substrate 5 formed of, for example, SiC, SiO₂, or sapphire. An alkaline earth chalcogenide such as CaO is grown on the substrate 5, which can be heated by a heater 7.

Cells 2a to 2d and an RF radical cell 3a are disposed opposite the substrate 5 held by the substrate holder 4. The cell 2a contains Ca as a constituent (source) of the compound to be grown. The cell 2b contains the element having an incomplete outermost p-electron shell, such as B, C, N, O, F, Si, or Ge (although the single cell 2b is illustrated, two or more cells 2b may be provided to dissolve two or more elements having an incomplete outermost p-electron shell). The cell 2c contains an n-type dopant such as Sc, Y, F, Cl, Ba, or I. The cell 2d contains a p-type dopant such as Li, Na, K, Rb, Cs, Fr, N, P, As, Sb, or Bi. The RF radical cell 3a generates oxygen radicals (O). Solid metal sources such as Ca may also be contained in the cells in the form of a chalcogenide that is decomposed into atoms in use.

Although not illustrated, the cells 2a to 2d, which contain solids (elemental substances), can be separately provided and heated to evaporate the solid sources into atomic form. The radical cell 3a is activated by a radio frequency (RF) coil 8 shown in FIG. 1. The solid sources of Ca, the element having an incomplete outermost p-electron shell, and the n-type dopant have a purity of 99.99999% and are decomposed into atomic form in use. Atomic oxygen is generated by activating the radical cell. Ca, O, and the element having an incomplete outermost p-electron shell can also be decomposed into atomic form by irradiating a molecular gas with an electromagnetic wave in the microwave region.

The element having an incomplete outermost p-electron shell is added during the deposition of CaO. While a thin CaO film 6 is grown at a substrate temperature of 250° C. to 750° C., the n-type dopant, such as Sc, Y, F, Cl, Ba, or I, the p-type dopant in atomic form, such as Li, Na, K, Rb, Cs, Fr, N, P, As, Sb, or Bi, and the element having an incomplete 2p-electron shell in atomic form, such as B, C, N, O, or F, are simultaneously supplied to the substrate 5 at 1.53×10⁻⁵ Pa, 6.40×10⁻⁵ Pa, and 1.53×10⁻⁵ Pa, respectively. Thus, a desired magnetic state can be achieved according to design by changing the atomic species of a transparent ferromagnetic semiconductor that exhibits ferromagnetic and spin-glass states.

Although a thin film of an alkaline earth chalcogenide containing an element having an incomplete outermost p-electron shell is deposited using the MBE (molecular beam epitaxy) apparatus in the example above, the film may also be deposited similarly using an MOCVD (metal organic chemical vapor deposition) apparatus.

Methods such as MBE and MOCVD allow deposition in a nonequilibrium state to heavily dope the alkaline earth chalcogenide with the element having an incomplete outermost p-electron shell to a desired concentration. The deposition method used is not limited to the examples above, and laser ablation may also be used to deposit a thin film on a substrate using solid sources of the alkaline earth chalcogenide and the element having an incomplete outermost p-electron shell as targets while spraying activated dopants onto the substrate.

While the alkaline earth chalcogenide is doped with the n-type dopant and the p-type dopant in the example described above, no dopant is used and only the element having an incomplete outermost p-electron shell, such as C or N, is dissolved in examples described below with reference to FIGS. 2 and 3 and Tables 1 and 2.

FIG. 2 shows variations in ferromagnetic transition temperature (Tc(K)) for different concentrations of C or N dissolved in CaO (impurity concentration; atomic percent). FIG. 3 shows concentrations of B, C, or N dissolved in CaO (impurity concentration; atomic percent) and differences ΔE (meV) in total energy between an antiferromagnetic spin-glass state and a ferromagnetic state, where positive values indicate that the ferromagnetic state is stable and negative values indicate that the antiferromagnetic spin-glass state is stable. The differences ΔE in total energy between the antiferromagnetic spin-glass state and the ferromagnetic state in FIG. 3 suggest that ferromagnetism can be imparted to the compound only by dissolving a substance having an incomplete outermost p-electron shell alone.

According to FIG. 3, a thin CaO film containing 5 atomic percent of C and a thin CaO film containing 5 atomic percent of N have large differences ΔE in total energy between the antiferromagnetic spin-glass state and the ferromagnetic state, namely, 0.2521×13.6 meV and 0.1720×13.6 meV, respectively. These films thus exhibit stable ferromagnetism.

FIG. 4 shows densities of electron states of C dissolved in CaO in the case where the content of C is 5 atomic percent of that of O in CaO. The horizontal axis indicates the energy relative to the Fermi energy, and the vertical axis indicates densities of states (states/cell eV) Similarly, FIG. 5 shows densities of electron states of N dissolved in CaO in the case where the content of N is 5 atomic percent of that of O in CaO. Similarly, FIG. 6 shows densities of electron states of Si dissolved in CaO in the case where the content of Si is 3 atomic percent of that of O in CaO. Any of these compounds exhibits a half-metallic state (metallic for spin-up electrons and semiconducting for spin-down electrons). Ferromagnetism can be achieved even if the concentration of at least one element having an incomplete outermost p-electron shell is only several atomic percent, and the dissolved element does not impair crystallinity or transparency for higher concentrations. The concentration of the dissolved element is preferably 1 to 25 atomic percent because such a compound can easily achieve sufficient ferromagnetism. The element can also be dissolved at any higher concentration, although concentrations exceeding the solid solubility limit are undesirable because such concentrations can impair the inherent crystallinity of the compound. As described below, the number of elements dissolved is not limited to one element, and two or more elements having an incomplete outermost p-electron shell can also be dissolved in the compound.

The element having an incomplete outermost p-electron shell is dissolved in CaO in this example, although compounds other than CaO, such as BeO, BeS, BeSe, BeTe, MgO, MgS, MgSe, MgTe, CaO, CaS, CaSe, CaTe, SrO, SrS, SrSe, SrTe, BaO, BaS, BaSe, BaTe, RaO, RaS, RaSe, and RaTe (hereinafter collectively referred to as CaO-type compounds), may also be used. The wavelength of light transmitted can be varied by controlling a band gap of a CaO-type compound. A CaO-type compound can be used to produce a single-crystal, completely spin-polarized (half-metallic) transparent ferromagnetic semiconductor, as in the case where the element having an incomplete outermost p-electron shell is dissolved in CaO.

In a half-metallic material, as shown in FIGS. 4 to 6, electron states exist only in one spin state at the Fermi energy while no electron states cannot exist in the opposite spin state at the Fermi energy because of the presence of a band gap. Hence, completely spin-polarized electrons are itinerant in the material. This material can be essential for spin injection into another material and development of magnetic memory and processor-related devices based on complete spin polarization with an insulator sandwiched by the material.

The completely spin-polarized half-metallic transparent ferromagnetic CaO-type compound according to the present invention forms a mixed crystal with the element having an incomplete outermost p-electron shell. This compound maintains its rock-salt structure with O²⁻ replaced with, for example, B²⁻, C²⁻, or N²⁻, any of which has an incomplete outermost p-electron shell. In addition, the element having an incomplete outermost p-electron shell, such as B, C, or N, has an electron structure in which holes or electrons are itinerant in the impurity band formed in the wide band gap. Thus, as shown in FIG. 3, the ferromagnetic state is stabilized only by doping with the element having an incomplete outermost p-electron shell, rather than doping with electrons or holes.

This half-metallic transparent ferromagnetic CaO-type compound has a large magnetic moment, specifically, 1.30×9.274 J/T (1.30μ_{B} (Bohr magneton)) for C and 0.631×9.274 J/T (0.631μ_{B}) for N, as shown in Tables 1 and 2 below. The CaO-type compound is thus a strong, completely spin-polarized transparent ferromagnet.

The amount of holes or electrons can be varied to change the ferromagnetic state by doping with an n-type dopant or a p-type dopant. Electrons or holes introduced by the n-type dopant or the p-type dopant enter an impurity band formed in the band gap of CaO by strong hybridization between p orbitals of the element having an incomplete outermost p-electron shell and those of CaO to change the ferromagnetic state, particularly, change the ferromagnetic transition temperature. For example, doping with an n-type dopant results in a supply of electrons.

FIG. 7 shows the relationship between hole and electron concentrations (%) and Curie temperatures (K) after doping with an n-type dopant and a p-type dopant (doping with holes) in the case of C or N, which significantly changes the difference ΔE in total energy between the antiferromagnetic spin-glass state and the ferromagnetic state after doping with an n-type dopant or a p-type dopant.

According to FIG. 7, the introduction of a large amount of holes lowers the stability of the ferromagnetic state, and doping with electrons using an n-type dopant attenuates the ferromagnetism, so that the ferromagnetic properties can be controlled. On the other hand, a material in which B, for example, is dissolved as the element having an incomplete outermost p-electron shell exhibits a spin-glass state. For this material, as opposed to the case of C or N, doping with holes stabilizes the ferromagnetic state and increases the ferromagnetic transition temperature, thus providing ferromagnetism. The ferromagnetic transition temperature can be controlled by varying the hole concentration, that is, the concentration of the p-type dopant.

The n-type dopant used may be Sc, Y, F, Cl, Ba, or I, and chalcogenides thereof may also be used as the source material for doping. The donor concentration is preferably at least 1×10¹⁸ cm⁻³. For example, a dosage of about 10²⁰ to 10²¹ cm⁻³ is equivalent to 1 to 10 atomic percent in terms of the concentrations described above. The p-type dopant used, as described above, may be Li, Na, K, Rb, Cs, Fr, N, P, As, Sb, or Bi. Although the doping with the p-type dopant is not easy in this case, the concentration of the p-type dopant can be increased by simultaneous doping with a slight amount of n-type dopant.

Although CaO is used as an example in the description above, CaO-type compounds other than CaO may also be used. FIGS. 8 to 11 show the cases where C is dissolved in MgO, SrO, and BaO as the element having an incomplete outermost p-electron shell. FIG. 8 shows variations in ferromagnetic transition temperature (Tc(K)) for different concentrations of C dissolved in MgO, SrO, or BaO. FIG. 9 shows densities of electron states in the case where 5 atomic percent of C is dissolved in MgO. FIG. 10 shows densities of electron states in the case where 5 atomic percent of C is dissolved in SrO. FIG. 11 shows densities of electron states in the case where 5 atomic percent of C is dissolved in BaO. In FIGS. 9 to 11, the horizontal axis indicates the energy relative to the Fermi energy, and the vertical axis indicates densities of states (states/cell eV). Any of these compounds exhibits a half-metallic state (metallic for spin-up electrons and semiconducting for spin-down electrons). The concentration of C is preferably 0.5 to 6 atomic percent for MgO and 5 to 25 atomic percent for SrO and BaO in view of achieving a high ferromagnetic transition temperature.

Although alkaline earth chalcogenides are used as examples in the description above, alkali chalcogenides may also be used. FIG. 12 shows the relationship between impurity concentrations (atomic percent) and differences ΔE (meV) in total energy between the antiferromagnetic spin-glass state and the ferromagnetic state in the case where Si or Ge is dissolved in K₂S as the element having an incomplete outermost p-electron shell, where positive values indicate that the ferromagnetic state is stable and negative values indicate that the antiferromagnetic spin-glass state is stable.

FIG. 13 shows variations in ferromagnetic transition temperature (Curie temperature (K)) for different concentrations of Si or Ge dissolved in K₂S. FIG. 14 shows the relationship between hole and electron concentrations (%) and ferromagnetic transition temperatures (Curie temperatures (K)) in the case where 10 atomic percent of Si is dissolved in K₂S and the solid solution is doped with an n-type dopant and a p-type dopant. FIG. 15 shows densities of electron states in the case where 10 atomic percent of Si is dissolved in K₂S. The horizontal axis indicates the energy relative to the Fermi energy, and the vertical axis indicates densities of states (states/cell eV). This compound exhibits a half-metallic state (metallic for spin-up electrons and semiconducting for spin-down electrons). The concentration of Si or Ge is preferably 5 to 25 atomic percent in view of achieving a high ferromagnetic transition temperature.

According to the present invention, as described above, the kinetic energy of holes or electrons introduced by, for example, dissolving the element having an incomplete outermost p-electron shell can change the total energy of the ferromagnetic state. The amount of holes or electrons introduced can be adjusted so as to decrease the total energy, thereby stabilizing the ferromagnetic state. In addition, the introduction of holes or electrons greatly changes the magnitude and sign of interatomic magnetic interaction. The interatomic magnetic interaction can thus be controlled with the introduced holes or electrons to stabilize the ferromagnetic state, or conversely to lower the stability and attenuate the ferromagnetism, thereby providing an antiferromagnetic spin-glass state.

### EXAMPLES

Variations in magnetic properties for different concentrations of the element having an incomplete outermost p-electron shell were examined. In addition to the compounds containing 5 atomic percent of the element having an incomplete outermost p-electron shell, compounds containing 15 atomic percent of the element and compounds containing 20 atomic percent of the element were prepared and examined for magnetic moment (×9.247 J/T) and ferromagnetic transition temperature (K). The magnetic moment and the ferromagnetic transition temperature were determined from measurements of susceptibility using an SQUID (superconducting quantum interference device). The results are shown in Tables 1 and 2.

TABLE 1

| | Concentration | | |
|---|---|---|---|
| | of element | | |
| Type of element | having | | |
| having | incomplete | | |
| incomplete | outermost 2p- | | Ferromagnetic |
| outermost 2p- | electron shell | Magnetic moment | transition |
| electron shell | (at %) | (μ_{B}) | temperature (K) |
| C | 5 | 1.30 | 531 |
| N | 5 | 0.631 | 362 |

TABLE 2

| | Concentration | | |
|---|---|---|---|
| | of element | | |
| Type of element | having | | |
| having | incomplete | | |
| incomplete | outermost 2p- | | Ferromagnetic |
| outermost 2p- | electron shell | Magnetic moment | transition |
| electron shell | (at %) | (μ_{B}) | temperature (K) |
| C | 20 | 1.31 | 484 |
| N | 20 | 0.702 | 413 |

As described above, the element having an incomplete outermost p-electron shell enters a high-spin state. Tables 1 and 2, and also FIG. 2, demonstrate that ferromagnetic spin-spin interaction and ferromagnetic transition temperature can be controlled by varying the concentration of the element.

### INDUSTRIAL APPLICABILITY

Transparent ferromagnetic compounds according to the present invention can be used in combination with fiber optics or transparent conductive oxides (TCOs) such as ZnO, which have been commercialized for n-type and p-type transparent electrodes, for applications including quantum computers, high-volume magneto-optical recording, optoelectronics ranging from the visible to ultraviolet region, and high-performance information communication.

### BRIEF DESCRIPTION OF THE DRAWINGS

FIG. 1 is a schematic diagram of an example of an apparatus for forming a single-crystal thin film of a completely spin-polarized transparent ferromagnetic compound according to the present invention.

FIG. 2 is a graph showing variations in ferromagnetic transition temperature (Tc(K)) for different concentrations of C or N dissolved in CaO.

FIG. 3 is a graph showing differences ΔE (meV) in total energy between an antiferromagnetic spin-glass state and a ferromagnetic state in the case where B, C, or N is dissolved in CaO.

FIG. 4 is a graph showing densities of electron states of C dissolved in CaO.

FIG. 5 is a graph showing densities of electron states of N dissolved in CaO.

FIG. 6 is a graph showing densities of electron states of Si dissolved in CaO.

FIG. 7 is a graph showing variations in ferromagnetic transition temperature (Curie temperature (K)) in the case where C is dissolved in CaO and the solid solution is doped with an n-type dopant and a p-type dopant.

FIG. 8 is a graph showing variations in ferromagnetic transition temperature (Tc(K)) for different concentrations of C dissolved in MgO, SrO, or BaO.

FIG. 9 is a graph showing densities of electron states (states/cell eV) in the case where 5 atomic percent of C is dissolved in MgO.

FIG. 10 is a graph showing densities of electron states (states/cell eV) in the case where 5 atomic percent of C is dissolved in SrO.

FIG. 11 is a graph showing densities of electron states (states/cell eV) in the case where 5 atomic percent of C is dissolved in BaO.

FIG. 12 is a graph showing differences ΔE (meV) in total energy between an antiferromagnetic spin-glass state and a ferromagnetic state in the case where Si or Ge is dissolved in K₂S.

FIG. 13 is a graph showing variations in ferromagnetic transition temperature (Curie temperature (K)) for different concentrations of Si or Ge dissolved in K₂S.

FIG. 14 is a graph showing variations in ferromagnetic transition temperatures (Curie temperatures (K)) in the case where 10 atomic percent of Si is dissolved in K₂S and the solid solution is doped with an n-type dopant and a p-type dopant.

FIG. 15 is a graph showing densities of electron states (states/cell eV) in the case where 10 atomic percent of Si is dissolved in K₂S.

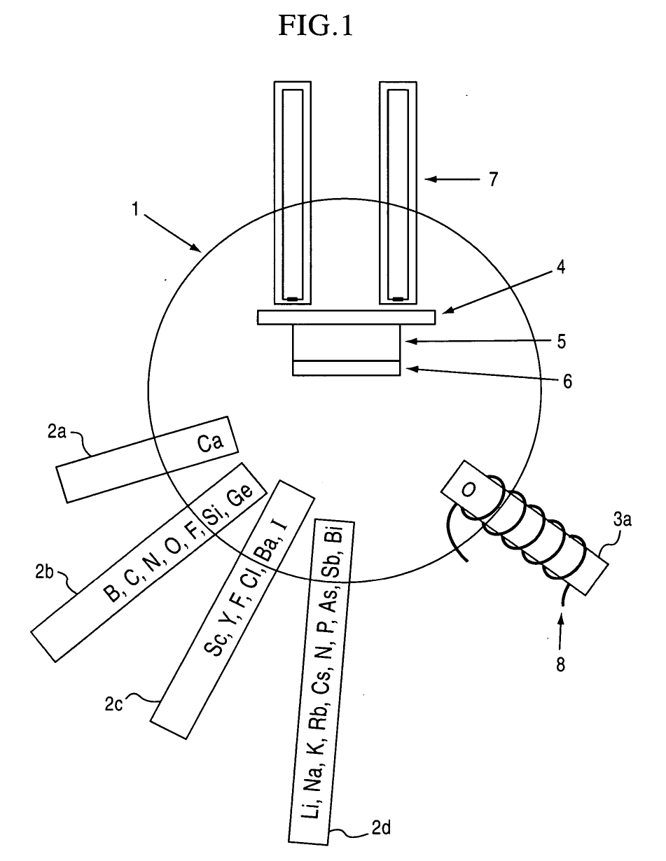

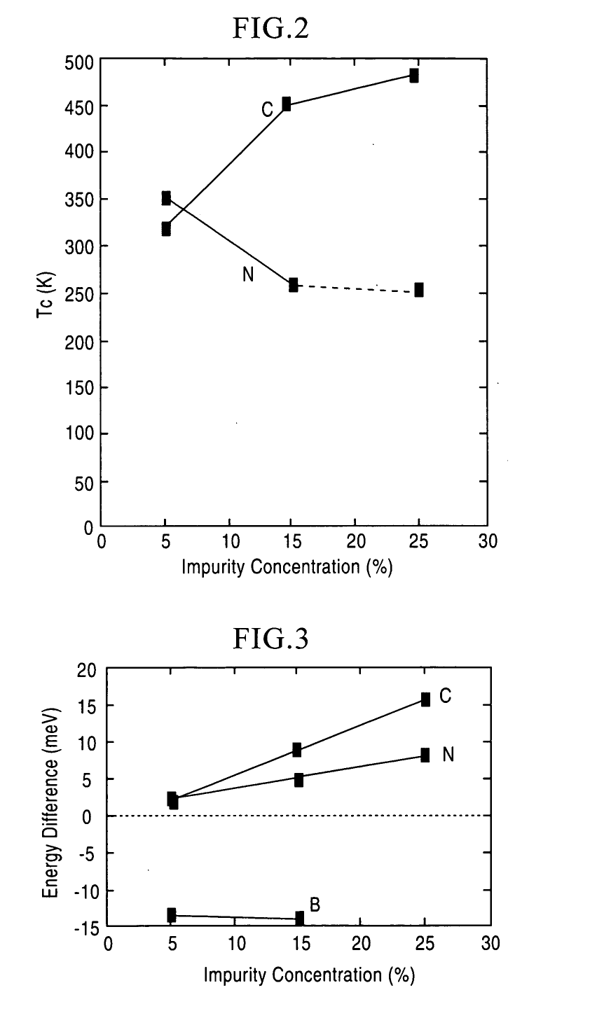

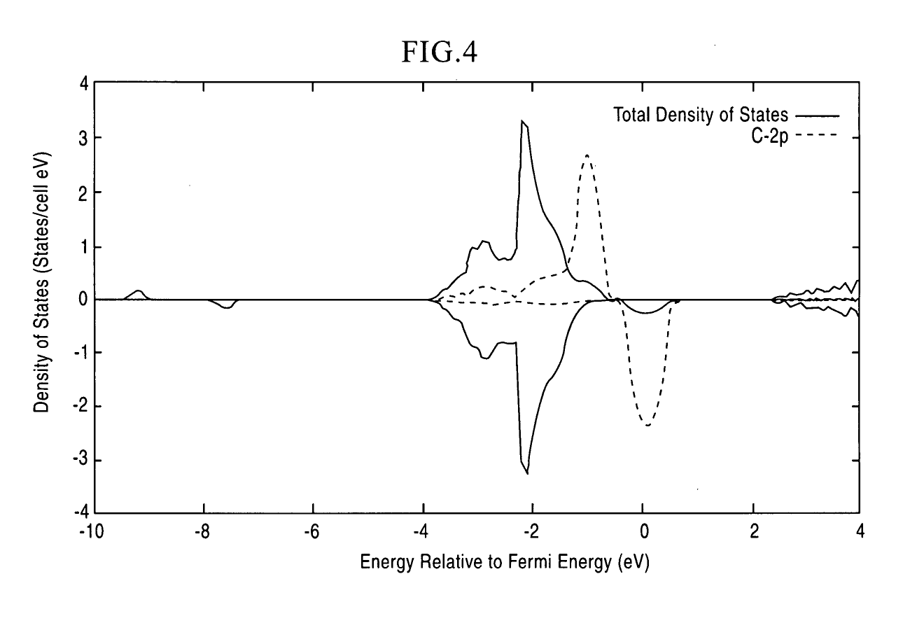

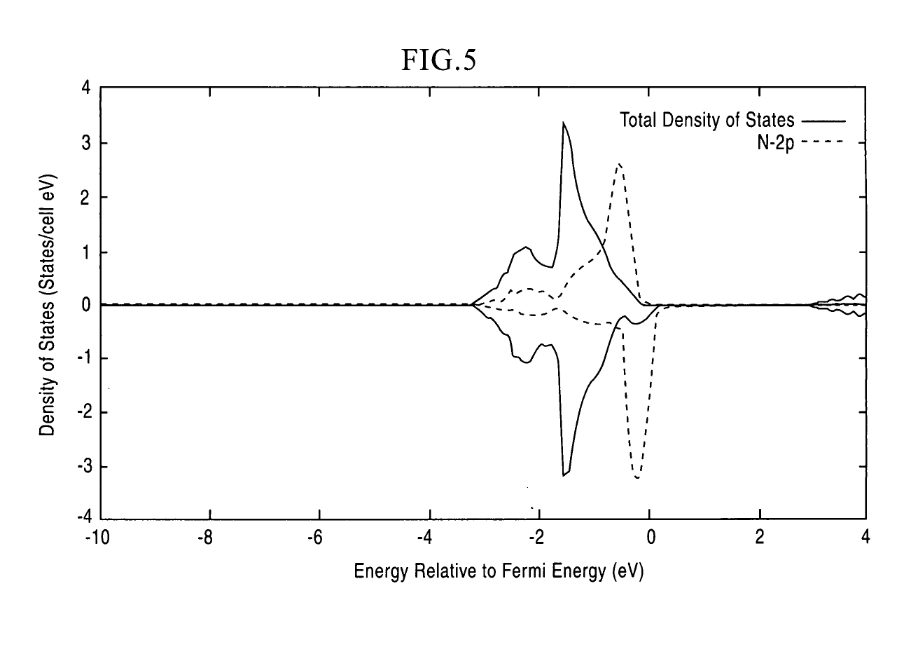

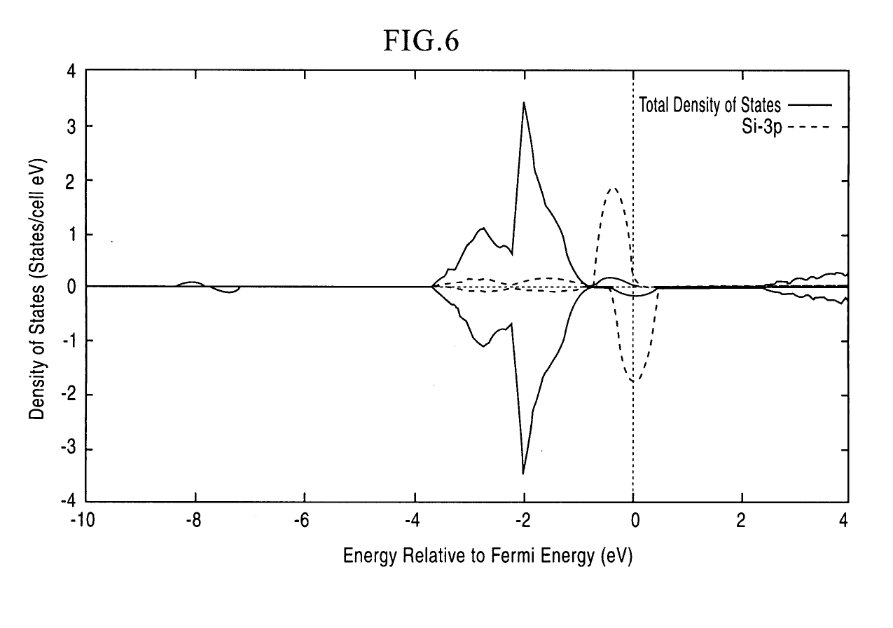

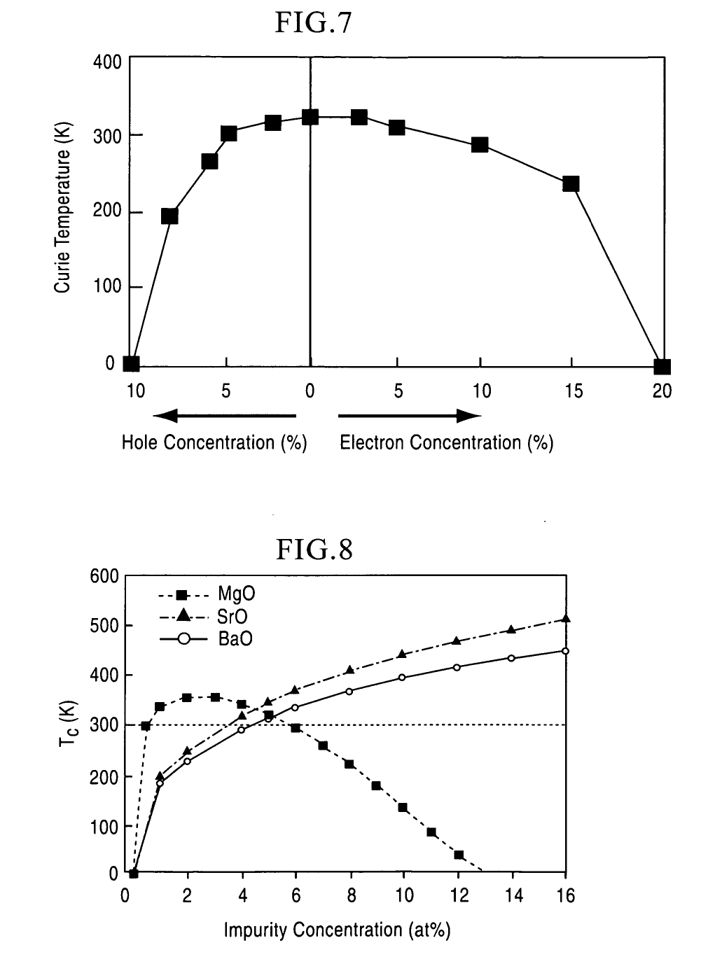

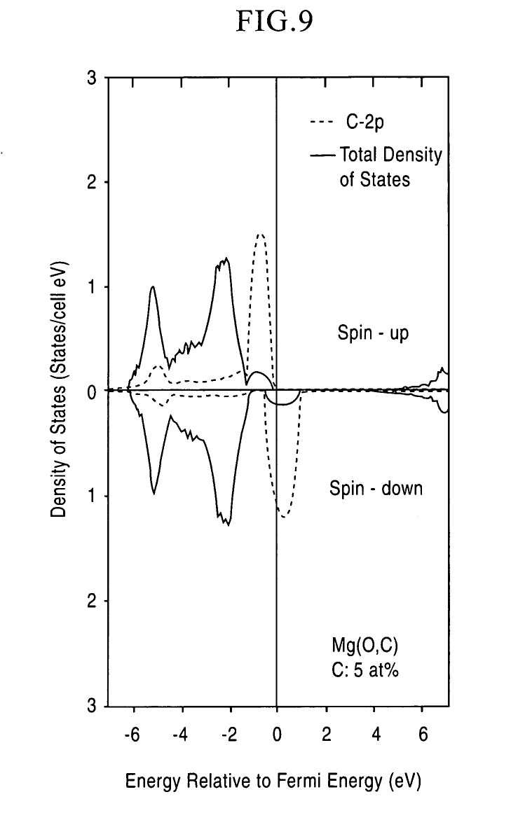

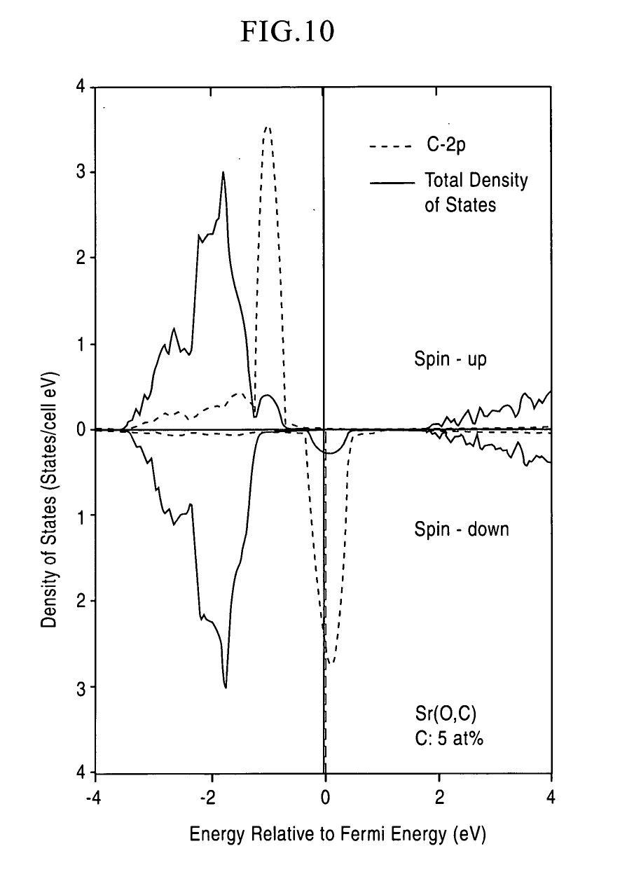

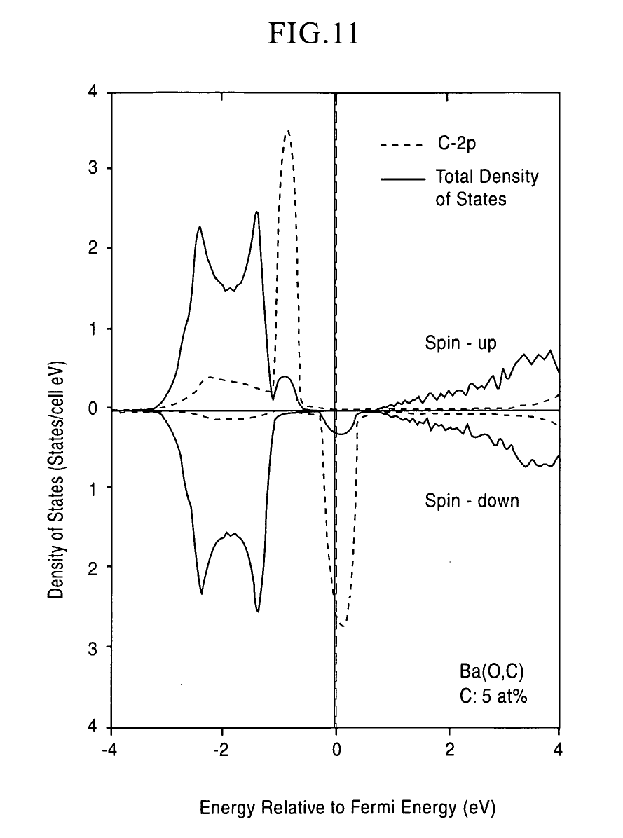

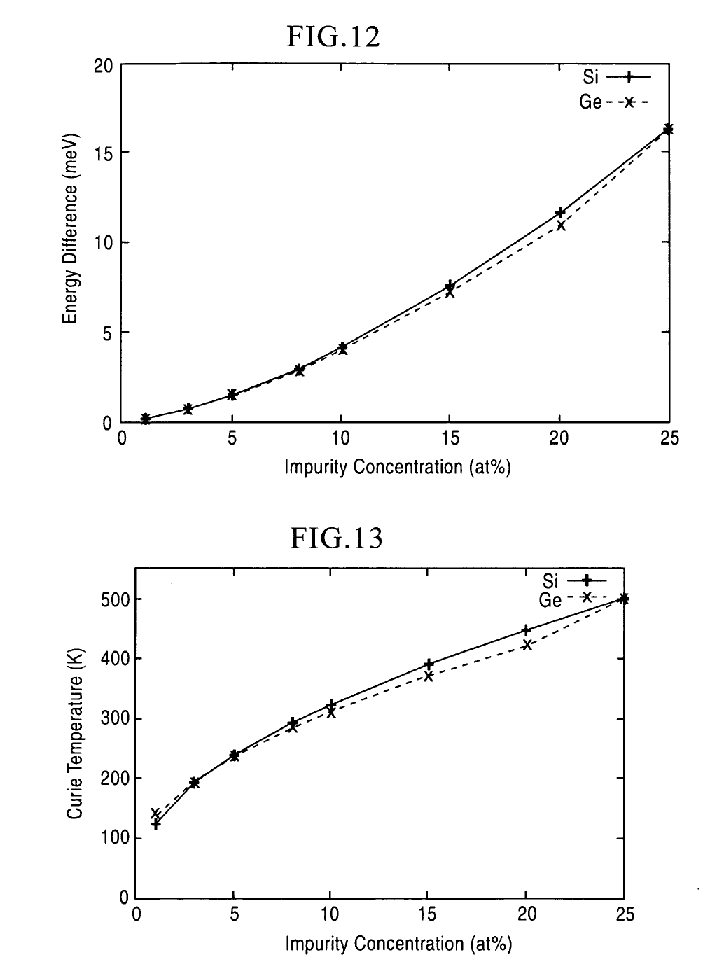

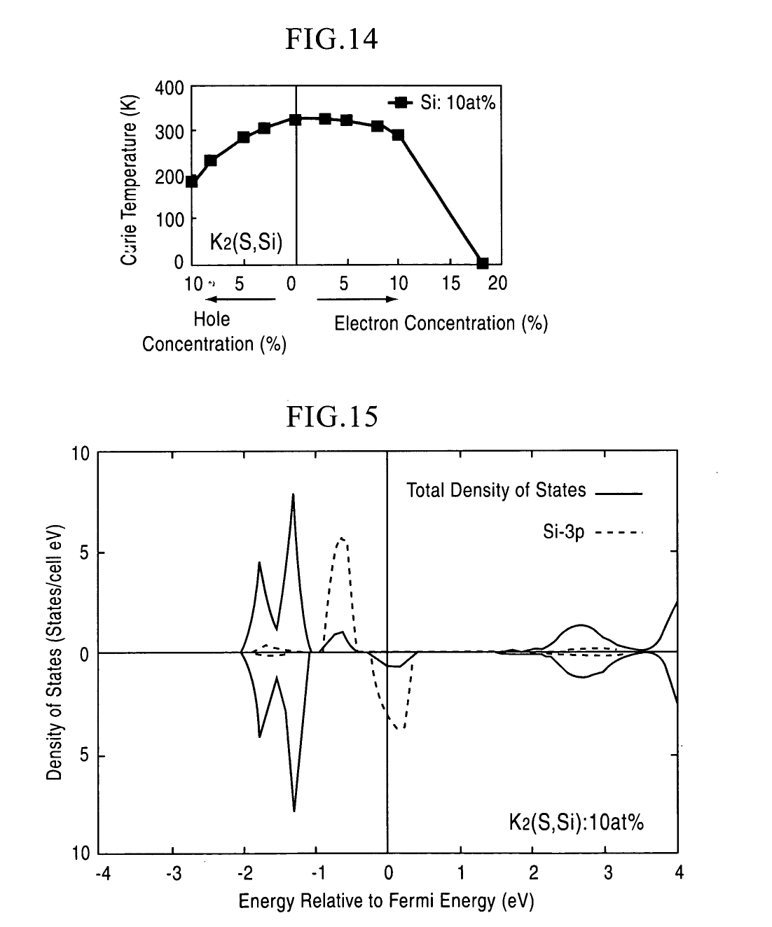

### REFERENCE NUMERALS

1 chamber

2a, 2b, 2c, 2d, and 3a cell

4 substrate holder

5 substrate

6 thin CaO film containing element having incomplete outermost p-electron shell

7 heater

1. A single-crystal transparent ferromagnetic compound selected from the group consisting of alkaline earth chalcogenides, alkali chalcogenides, I-VII compounds, II-VI compounds, III-V compounds, IV-VI₂ compounds, IV-IV compounds, and II-VII₂ compounds, wherein at least one element having an incomplete outermost p-electron shell is dissolved so that the compound has a ferromagnetic transition temperature of room temperature or higher.

2. The single-crystal transparent ferromagnetic compound according to claim 1, comprising an alkaline earth chalcogenide selected from the group consisting of MgO, CaO, SrO, and BaO or an alkali chalcogenide comprising K₂S, wherein the element having an incomplete outermost p-electron shell is C, N, Si, or Ge.

3. The transparent ferromagnetic compound according to claim 1, being doped with at least one of an n-type dopant and a p-type dopant.

4. A method for producing the single-crystal transparent ferromagnetic compound according to claim 1, comprising depositing the compound selected from the group consisting of alkaline earth chalcogenides, alkali chalcogenides, I-VII compounds, II-VI compounds, III-V compounds, IV-VI₂ compounds, IV-IV compounds, and II-VII₂ compounds while adding the element having an incomplete outermost p-electron shell.

5. A method for controlling the ferromagnetic properties of the single-crystal transparent ferromagnetic compound in the method according to claim 4, comprising adjusting the concentration of the dissolved element to control the ferromagnetic properties.

6. A method for controlling the ferromagnetic properties of the transparent ferromagnetic compound in the method according to claim 4, comprising additionally doping the compound with at least one of an n-type dopant and a p-type dopant in the deposition.

7. The method for controlling the ferromagnetic properties of the transparent ferromagnetic compound according to claim 5 or 6, wherein ferromagnetic transition temperature is controlled among the ferromagnetic properties.

8. The method for controlling the ferromagnetic properties of the transparent ferromagnetic compound according to claim 5 or 6, wherein the ferromagnetic properties are controlled by adjusting the energy of a ferromagnetic state and adjusting the number of carriers with holes or electrons introduced by the dissolved element so that the total energy of the ferromagnetic state is decreased relative to that of a spin-glass state to stabilize a desired ferromagnetic state relative to the spin-glass state, thereby developing the ferromagnetic state.

9. The method for controlling the ferromagnetic properties of the transparent ferromagnetic compound according to claim 5 or 6, wherein the ferromagnetic properties are stabilized by controlling the magnitude and sign of interatomic magnetic interaction with holes or electrons introduced by the dissolved element.

10. The method for controlling the ferromagnetic properties of the transparent ferromagnetic compound according to claim 5 or 6, wherein a ferromagnetic compound having desired optical filtering properties are achieved by controlling the magnitude and sign of interatomic magnetic interaction with holes or electrons introduced by the dissolved element having an incomplete outermost p-electron shell and adjusting the magnitude of a band gap with the dissolved element to control optical transmission properties.
